(19) United States
(12) Patent Application Publication
(10) Pub. No.: US 2005/0032389 A1
(43) Pub. Date: Feb. 10, 2005

(54) Method for avoiding erosion of DRAM fuse sidewall

(75) Inventor: Kuo-Chien Wu, Miaoli (TW)

Correspondence Address: BACON & THOMAS, PLLC, 625 SLATERS LANE, FOURTH FLOOR, ALEXANDRIA, VA, 22314, US

(73) Assignee: Nanya Technology Corporation, Taoyuan (TW)

(21) Appl. No.: 10/633,525

(22) Filed: Aug. 5, 2003

(51) Int. Cl. H01L 21/302; H01L 21/461

(52) U.S. Cl. 438/724

(57) ABSTRACT

Disclosed is a method for avoiding the erosion of DRAM fuse sidewall. The method comprises the steps of forming a fuse on a substrate, depositing a dielectric layer on the substrate and the fuse, depositing operation layers on the dielectric layer to construct an intermediate structure, applying photoresist to the intermediate structure and etching the same to form a fuse opening so that the fuse is exposed, removing the photoresist, depositing a separate layer to cover at least the exposed portion of the fuse, and etching the separate layer so that the left separate layer covers at least the sidewall of the fuse. Disclosed also is a fuse structure of a DRAM. The fuse structure is characterized in that the sidewall of the fuse is covered with a separate layer having protecting function. Therefore, it is avoided that water left at the lower portion of the fuse in cleaning step reacts with the sidewall of the fuse to cause the damage of the structure.

### BACKGROUND OF THE INVENTION

1. Field of the Invention

This invention relates to a method for preventing DRAM fuse sidewall from being eroded, and to a DRAM structure manufactured based on the method of the present invention. In the method, a separate layer is deposited on the fuse including the sidewall thereof. The separate layer has the function of preventing the lower portion of the fuse sidewall from being eroded and accordingly damaged.

2. Description of the Prior Art

Up to now, it is found that the fuse of the DRAM component is often damaged during the cleaning step after the protective layer is etched in the 0.14 μm manufacture process of DRAM. This is because that in the cleaning step, the deionized water left around the lower portion of the fuse can hardly be dried completely, so that the CO₂ in the deionized water will react with the sidewall of the fuse, for instance, react with Al to generate Al₂O₃, causing the metal of the fuse sidewall eroded and damaged.

Nowadays, the conventional method for manufacturing the fuse of DRAM components is to form metal fuse M1 on a substrate first and use high density plasma and plasma enhanced deposition or the like to deposite a dielectric layer, which can be an oxide layer. Then, after such steps as chemical and mechanical polishing, exposing and etching, metal M2 is deposited and etched. For instance, the metal M2 can serve as a metal pad. Subsequently, an oxide layer is formed, and a SiN layer is deposited on the oxide layer. Then, a photoresist is formed on the entire structure, and etching is performing to form a metal pad opening and a fuse opening. In the end, a protective layer is coated, which can be a polyimide layer that can be cured by illumination. Finally a product is made.

However, deionized water for cleaning will be left around the fuse during cleaning, if DRAM components are manufactured based on the above conventional method. If the fuse is soaked for a long time, the sidewall of the fuse is likely to react with the CO₂ in the deionized water so that a metal oxide is generated, and thus the sidewall of the fuse will be eroded and damaged.

Therefore, the inventor of the present invention has devoted himself in developing a novel method, in which a separate layer is formed on the sidewall around the fuse to prevent the sidewall from being eroded and damaged by the residuary moisture to affect the product performance.

### SUMMARY OF THE INVENTION

An objective of the present invention is to provide a method to prevent DRAM fuse sidewall from being eroded. A separate layer is formed around the fuse to protect the sidewall of the fuse from being eroded and damaged due to the reaction between the sidewall and the residuary moisture remaining around the fuse during cleaning.

Another objective of the present invention is to provide a structure obtained based on the above novel method.

According to one aspect of the present invention, a novel method for preventing DRAM fuse sidewall from being eroded comprises the following steps: forming a fuse on a substrate; forming a dielectric layer on the substrate, the dielectric layer also covering the fuse; forming operating layers on the dielectric layer to construct an intermediate structure; forming a photoresist on the intermediate structure, and performing etching to from a fuse opening so that the fuse is exposed; removing the photoresist; forming a separate layer to cover the exposed portion of the fuse at least; and etching the separate layer to remove unnecessary portion.

According to another aspect of this invention, after removing its unnecessary portions, the remaining portion of the separate layer can cover the sidewall of the fuse at least.

According to a further aspect of the present invention, the DRAM component fuse structure manufactured by this method has a separate layer formed around the sidewall of the fuse at least, which has a protective function to prevent the structure from being damaged due to the reaction between the residuary moisture remaining around the fuse and the sidewall of the fuse.

### BRIEF DESCRIPTION OF THE DRAWINGS

FIG. 1 is a schematic diagram showing areas around a metal fuse of an intermediate structure after operating layers are formed in DRAM manufacture;

FIG. 2 is a schematic diagram showing a structure in FIG. 1 has an opening formed by forming a photoresist layer and etching;

FIG. 3 is a schematic diagram showing a structure obtained after the structure in FIG. 2 has a separate layer formed and etched; and

FIG. 4 is the schematic diagram showing the final structure obtained by forming a protective layer structure of FIG. 3.

### DETIALED DESCRIPTION OF THE PREFERRED EMBODIMENT

The technical contents, purposes and effects achieved as revealed by the present invention will be further explained in detail in the following embodiment.

First, a substrate 10 is provided. A metal fuse M1 is formed on the substrate 10 by deposition and etching.

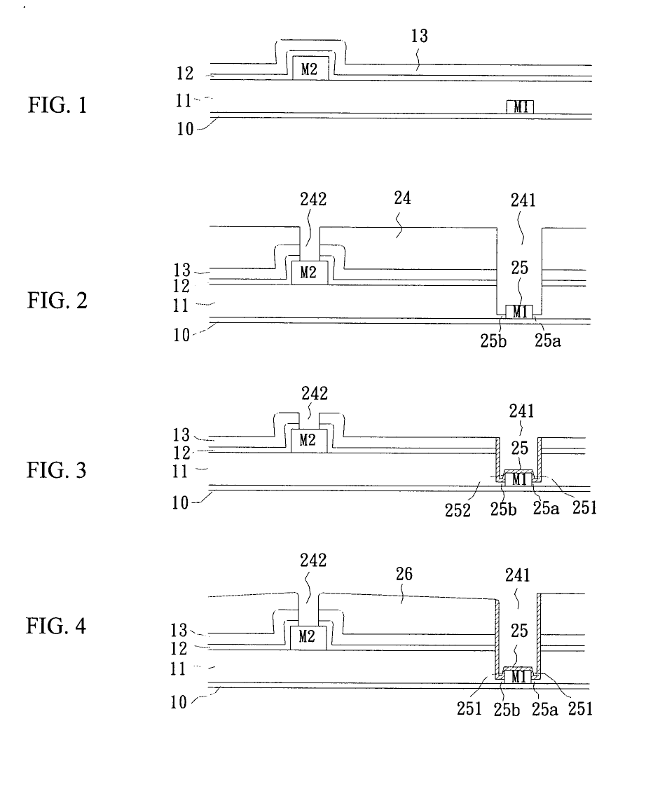

A dielectric layer 11, which can be an oxide layer, is deposited on the substrate 10 and the metal fuse M1 by high density plasma or plasma enhanced deposition process. The dielectric layer can be processed with CMP, and with any proper treatments as required. Subsequently, a metal portion M2 is deposited on the dielectric layer 11 and is etched as a metal pad, for example, of a predetermined dimension. Then, operating layers for other purposes, such as an oxide layer 12 and a SiN layer 13, are formed on the dielectric layer 11 and the metal portion M2. Accordingly, a intermediate structure is obtained as shown in FIG. 1. A photoresist layer 24 is formed on the SiN layer as a mask. After etching, a metal pad opening 242 and a fuse opening 241 are formed, as shown in FIG. 2.

Then, the remaining photoresist layer is removed and a separate layer 25 is deposited on the entire structure, the material for the separate layers 25 can be Sin or SiON or any other proper materials. Then, the unnecessary portions of the separate layer 25 are etched and removed, while at lease the portion covering the sidewall of the metal fuse M1 is retained, as shown in FIG. 3.

In the end, a protective layer 26 is coated, which can use polyimide as its material and can be cured. Finally a product is made, as shown in FIG. 4.

Since the sidewall of the fuse in the product manufactured in accordance with the above embodiment is protected by the separate layer of nitride or nitrogen oxide, it will not be eroded due to its contact with the CO₂ in the water left around the fuse in the cleaning step, thereby maintaining the product in good performance and quality.

While the embodiment of the present invention is illustrated and described, various modifications and alterations can be made by persons skilled in this art. The embodiment of the present invention is therefore described in an illustrative but not restrictive sense. It is intended that the present invention may not be limited to the particular forms as illustrated, and that all modifications which maintain the spirit and realm of the present invention are within the scope as defined in the appended claims.

1. A method of preventing DRAM fuse sidewall from being eroded comprising steps of:
forming a fuse on a substrate;
forming a dielectric layer on the substrate, said dielectric layer covering the fuse;
forming at lease one work layer on the dielectric layer to constitute an intermediate structure;
forming a photoresist on the intermediate structure, and etching to form a fuse opening so that the fuse is exposed;
removing the photoresist;
forming a separate layer, said separate layer covering the exposed portion of the fuse at least; and
etching the separate layer to remove unnecessary portions thereof.

2. The method as recited in claim 1, wherein said separate layer, after its unnecessary portions are removed, covers the sidewall of the fuse at least.

3. The method as recited in claim 1, wherein said separate layer uses SiN as its material.

4. The method as recited in claim 1, wherein said separate layer uses SiON as its material.

5. The method as recited in claim 1, further comprising a step of forming a protective layer on the entire structure after the unnecessary portions of the separate layer are removed.

6. The method as recited in claim 1, wherein said protective layer uses a polymer as its material.

7. A fuse structure manufactured according to claim 1 or 2, which is characterized in that the sidewall of the fuse in the structure is covered with the separate layer.

8. The structure as recited in claim 7, wherein said separate layer uses SiN as its material.

9. The structure as recited in claim 7, wherein said separate layer uses SiON as its material.
